(19) United States
(12) Patent Application Publication
(10) Pub. No.: US 2021/0325576 A1
(43) Pub. Date: Oct. 21, 2021

(54) OPTICAL SYSTEM AND PROCESS FOR MANUFACTURING SAME

(71) Applicant: ISORG, Limoges CEDEX 3 (FR)

(72) Inventors: Wilfrid SCHWARTZ, GRENOBLE (FR); Quentin CHABLE, GRENOBLE (FR); Agathe PUSZKA, GRENOBLE (FR); Benjamin BOUTHINON, GRENOBLE (FR)

(21) Appl. No.: 17/260,949

(22) PCT Filed: Jul. 18, 2019
(86) PCT No.: PCT/EP2019/069453

§ 371 Date: Jan. 15, 2021

(30) Foreign Application Priority Data
Jul. 19, 2018 (FR) 18/56709

(51) Int. Cl. G02B 5/00; G02B 1/14; G02B 27/30

(52) U.S. Cl. CPC G02B 5/005; G02B 27/30; G02B 5/003; G02B 1/14

(57) ABSTRACT

A method of manufacturing an optical system including a layer having through or partially through holes and covered with an array of micrometer-range optical elements, the optical system including a surface intended to receive a first radiation, the method including exposing a film, made of the same material as the layer or of a material different from that of the layer, to a second radiation through the array of micrometer-range optical elements, the material being photosensitive to the second radiation or machinable by the second radiation, and removing the portions of the film exposed or non-exposed to the second radiation to delimit the holes totally or partially crossing said layer.

The present patent application claims the priority benefit of French patent application FR18/56709 which is herein incorporated by reference.

### TECHNICAL BACKGROUND

The present disclosure concerns optical systems and methods of manufacturing the same.

### PRIOR ART

An optical system is an assembly of optical elements, such as mirrors, lenses, diffraction gratings, etc. enabling to modify the trajectory of the light rays or the properties of light. An example of application of an optical system concerns an image acquisition system where the optical system is interposed between the sensitive portion of an image sensor and the object to be imaged and which enables to form a sharp image of the object to be imaged on the sensitive portion of the image sensor. Another example of application comprises coupling the optical system to a single photodetector, such as a photodiode, to control the light collected by the photodetector. Another example of application concerns a display or projection system where the optical system covers a light source, for example, a display screen, and enables to modify the radiation emitted by the light source, for example, to collimate the radiation emitted by each display pixel.

However, in certain cases, it is not possible to use a conventional optical system. For example, in the case of an image acquisition system, it may not be possible to place a conventional optical system between the sensitive portion of the image sensor and the object to be imaged. This is particularly true when the image sensor occupies a significant surface area, greater than one square centimeter, and the distance between the object to be imaged and the sensitive portion of the image sensor is smaller than one centimeter.

The object to be imaged would then have to be placed at closest to the image sensor so that the image which forms on the sensitive portion of the image sensor is sufficiently sharp. However, there may be a distance between the object and the image sensor, so that the sharpness of the image which forms on the sensitive portion of the image sensor may be insufficient for certain applications, for example, for the capture of fingerprints.

To increase the sharpness of the image acquired by the image sensor of an image acquisition system in the absence of a complex optical system, a possibility is to cover the image sensor with an optical system having a simple structure, playing the role of an angular filter, comprising an opaque layer crossed by openings, and covered with an array of micrometer-range optical elements, for example, an array of micrometer-range lenses, or microlens, an array of micrometer-range index gradient microlenses, or an array of micrometer-range diffraction gratings, each micrometer-range optical element being associated with an opening of the layer comprising openings.

An example of a method of manufacturing such an optical system comprises manufacturing the layer comprising openings, manufacturing the micrometer-range optical elements, and positioning the micrometer-range optical elements with respect to the layer comprising openings. The step of positioning the micrometer-range optical elements with respect to the layer comprising openings requires using alignment tools. Such alignment tools exist but generate a significant cost for the manufacturing of these optical systems and above all do not enable to manufacture these optical systems at a very large scale. Further, due to the use of organic materials, the layer comprising openings and/or the micrometer-range optical elements may comprise deformations, resulting from thermal and/or mechanical effects, so that the correct alignment of each micrometer-range optical element with the corresponding opening of the layer comprising openings may not be possible for all the micrometer-range optical elements.

### SUMMARY

An object of an embodiment is to totally or partly overcome the constraints due to the manufacturing of optical systems comprising a layer with openings and an array of micrometer-range optical elements and of their previously-described manufacturing methods.

An object of an embodiment is to be able to position the micrometer-range optical elements with respect to the openings of the layer comprising openings with a sufficient accuracy.

Another object of an embodiment is to be able to implement the optical system manufacturing method at an industrial scale.

For this purpose, an embodiment provides a method of manufacturing an optical system comprising a layer comprising through or partially through holes and covered with an array of micrometer-range optical elements. The optical system comprises a surface intended to receive a first radiation. The method comprises exposing a film, made of the same material as the layer or of a material different from that of the layer, to a second radiation through the array of micrometer-range optical elements, said material being photosensitive to the second radiation or machinable by the second radiation, and removing the portions of the film exposed or non-exposed to the second radiation to delimit the holes totally or partially crossing said layer.

According to an embodiment, the film is made of resist photosensitive to the second radiation.

According to an embodiment, the layer is made of resist positively photosensitive to the second radiation, the removed portions of the film being the portions exposed to the second radiation.

According to an embodiment, the film is made of resist negatively photosensitive to the second radiation, the removed portions of the film being the portions non-exposed to the second radiation.

According to an embodiment, the method comprises machining the layer with a laser beam.

According to an embodiment, the optical system forms an angular filter configured to block the rays of said first radiation having an incidence relative to a direction orthogonal to the surface in at least a first incidence range and to give way to rays of said first radiation having an incidence relative to a direction orthogonal to the surface in at least a second incidence range distinct from said at least one first incidence range.

According to an embodiment, the first radiation is different from the second radiation.

According to an embodiment, the first radiation is in the visible range and/or in the infrared range.

According to an embodiment, the second radiation is in the visible range and/or in the ultraviolet range.

According to an embodiment, the method comprises, at the exposure step, placing into contact the array of micrometer-range optical elements with a material, different from air, having a refraction index different from that of the micrometer-range optical elements.

According to an embodiment, the manufacturing of the optical system is performed roll to roll.

According to an embodiment, the method comprises, after the forming of the holes, the filling of the holes with a bonding material and the bonding of the layer comprising the holes to a device via the bonding material.

According to an embodiment, the second radiation is collimated.

According to an embodiment, the second radiation has a divergence angle greater than 1°.

An embodiment also provides an optical system comprising a surface intended to receive a first radiation, a layer comprising through or partially through holes and covered with an array of micrometer-range optical elements. The layer is made of a material or the holes are filled with said material, said material being photosensitive to a second radiation or machinable by the second radiation.

According to an embodiment, the layer is opaque to the first radiation, the system being configured to block the rays of said first radiation having an incidence relative to a direction orthogonal to the surface in at least a first incidence range and to give way to rays of said first radiation having an incidence relative to a direction orthogonal to the surface in at least a second incidence range distinct from said at least one first incidence range.

According to an embodiment, the material is resist photosensitive to second radiation.

According to an embodiment, the system comprises as many micrometer-range optical elements as holes, the pitch between the micrometer-range optical elements being the same as the pitch between holes.

According to an embodiment, for each hole, the ratio of the height of the hole, measured perpendicularly to the surface, to the width of the hole, measured parallel to the surface, varies from 1 to 10.

According to an embodiment, the holes are arranged in rows and in columns, the pitch between adjacent holes of a same row or of a same column varying from 1 μm to 100 μm.

According to an embodiment, the height of each hole, measured along a direction orthogonal to the surface, varies from 1 μm to 800 μm, particularly from 10 μm to 800 μm or from 1 μm to 100 μm.

According to an embodiment, the width of each hole, measured parallel to the surface, varies from 0.1 μm to 100 μm.

According to an embodiment, the system comprises a stack of said layer comprising said through or partially through holes and of an additional layer comprising additional through or partially through holes aligned with said holes.

An embodiment also provides an image acquisition system comprising an image sensor and an optical system, such as previously defined, covering the image sensor and forming an angular filter.

According to an embodiment, the image sensor comprises an array of photodetectors, the pitch between photodetectors being equal to, greater or smaller than the pitch between holes.

According to an embodiment, the optical system comprises an auxiliary layer playing the role of a protection layer for the image sensor.

According to an embodiment, the image sensor is at least partly made of organic materials, and the optical system comprises a water- and/or oxygen-tight film.

An embodiment also provides a lighting or display system comprising a light a source and an optical, such as previously defined, covering the light source.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of an embodiment of an optical system comprising a layer comprising openings covered with an array of microlenses;

FIG. 2 is a top view of the layer comprising openings of the optical system shown in FIG. 1;

FIG. 3 is a partial simplified cross-section view of a variant of the optical system shown in FIG. 1;

FIG. 4 is a partial simplified cross-section view of another variant of the optical system shown in FIG. 1;

FIG. 5 is a partial simplified cross-section view of an embodiment of an image acquisition system;

FIG. 6 is a partial simplified cross-section view of an embodiment of a lighting or projection system;

FIG. 7 is a partial simplified cross-section view of another embodiment of a lighting system;

FIG. 8 is a partial simplified cross-section view of the structure obtained at a step of an embodiment of a method of manufacturing the optical system shown in FIGS. 1 and 2;

FIG. 9 is a partial simplified cross-section view of the structure obtained at another step of an embodiment of a method of manufacturing the optical system shown in FIGS. 1 and 2;

FIG. 10 is a partial simplified cross-section view of the structure obtained at another step of an embodiment of a method of manufacturing the optical system shown in FIGS. 1 and 2;

FIG. 11 is a partial simplified cross-section view of the structure obtained at another step of an embodiment of a method of manufacturing the optical system shown in FIGS. 1 and 2;

FIG. 12 is a partial simplified cross-section view of the structure obtained at another step of an embodiment of a method of manufacturing the optical system shown in FIGS. 1 and 2;

FIG. 13 is a partial simplified cross-section view of the structure obtained at a step of another embodiment of a method of manufacturing the optical system shown in FIGS. 1 and 2; and

FIG. 14 is a partial simplified cross-section view of the structure obtained at another step of another embodiment of a method of manufacturing the optical system shown in FIGS. 1 and 2.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the structure of an image sensor is well known by those skilled in the art and is not described in detail hereafter.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., unless specified otherwise, it is referred to the orientation of the drawings or to an optical system in a normal position of use.

Unless specified otherwise, the expressions “around”, “approximately”, “substantially” and “in the order of” signify within 10%, and preferably within 5%.

In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%. According to an embodiment, for a same optical system, all the elements of the optical system which are opaque to a radiation have a transmittance which is smaller than half, preferably smaller than one fifth, more preferably smaller than one tenth, of the lowest transmittance of the elements of the optical system transparent to said radiation. In the rest of the disclosure, the expression “useful radiation” designates the electromagnetic radiation crossing the optical system in operation. In the following description, the expression “micrometer-range optical element” designates an optical element formed on a surface of a support having a maximum dimension, measured parallel to said surface, greater than 1 μm and smaller than 1 mm. In the following description, a film or a layer is said to be oxygen-tight when the permeability of the film or of the layer to oxygen at 40° C. is smaller than 1.10⁻¹cm³/(m²*day). The permeability to oxygen may be measured according to the ASTM D3985 method entitled “Standard Test Method for Oxygen Gas Transmission Rate Through Plastic Film and Sheeting Using a Coulometric Sensor”. In the following description, a film or a layer is said to be water-tight when the permeability of the film or of the layer to water at 40° C. is smaller than 1.10⁻¹ g/(m²*day) . The permeability to water may be measured according to the ASTM F1249 method entitled “Standard Test Method for Water Vapor Transmission Rate Through Plastic Film and Sheeting Using a Modulated Infrared Sensor”.

Embodiments of optical systems will now be described for optical systems comprising an array of micrometer-range optical elements in the case where each micrometer-range optical elements corresponds to a micrometer-range lens, or microlens. It should however be clear that these embodiments may also be implemented with other types of micrometer-range optical elements, where each micrometer-range optical element may correspond to a micrometer-range Fresnel lens, to a micrometer-range index gradient lens, or to a micrometer-range diffraction grating.

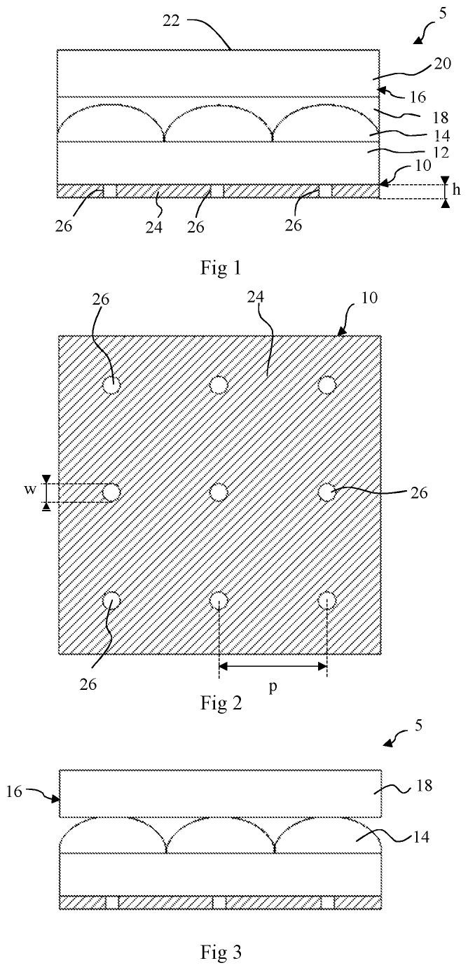

FIG. 1 is a partial simplified cross-section view of an embodiment of an optical system 5. Optical system 5 comprises, from bottom to top in FIG. 1:
a layer 10 comprising openings;
an intermediate layer 12 covering layer 10 comprising openings, which intermediate layer 12 may be omitted;
an array of micrometer-range optical elements 14, for example, an array of microlenses 14 covering intermediate layer 12, where intermediate layer 12 and microlens array 14 may correspond to a monolithic structure;
a coating 16 covering microlens array 14 and for example comprising a stack of a plurality of layers, for example, two layers 18 and 20, and comprising an upper surface 22, where coating 16 may be omitted, upper surface 22 then corresponding to the upper surface of microlens array 14.

FIG. 2 is a top view of the layer 10 comprising openings shown in FIG. 1. In the present embodiment, layer 10 comprising openings comprises an opaque layer 24 crossed by holes 26, also called openings. Preferably, holes 26 are through holes since they extend across the entire thickness of layer 24. According to another embodiment, holes 26 may only extend across a portion of the thickness of opaque layer 24, a residual portion of opaque layer 24 remaining at the bottom of holes 26. However, in this case, the thickness of the residual portion of opaque layer 24 at the bottom of hole 26 is sufficiently low for the assembly comprising hole 26, possibly filled, and the residual portion of opaque layer 24 at the bottom of hole 26 to be able to be considered as transparent to the useful radiation. Call “h” the thickness of layer 24. Layer 24 is opaque to all or part of the spectrum of radiation 42. Layer 24 may be opaque to the useful radiation used in operation, for example, absorbing and/or reflective with respect to the useful radiation. According to an embodiment, layer 24 is absorbing in the visible range or a portion of the visible range and/or near infrared and/or infrared.

In FIG. 2, holes 26 are shown with a circular cross-section. Generally, holes 26 may have any cross-section in top view, for example, circular, oval, or polygonal, particularly, triangular, square, or rectangular according to the manufacturing method used. Further, in FIG. 1, holes 26 are shown with a constant cross-section across the entire thickness of opaque layer 24. However, the cross-section of each hole 26 may vary across the thickness of opaque layer 24. In the case where holes 26 are formed by a method comprising photolithography steps, the hole shape may be adjusted by the method parameters such as the exposure dose and the development time as well as by the shape of the microlenses.

According to an embodiment, holes 26 are arranged in rows and in columns. Holes 26 may have substantially the same dimensions. Call “w” the width of a hole 26 measured along the row or column direction. Width w corresponds to the diameter of hole 26 in the case of a hole having a circular cross-section. According to an embodiment, holes 26 are regularly arranged along the rows and along the columns. Call “p” the pitch of holes 26, that is, the distance in top view between the centers of two successive holes 26 of a row or of a column.

Layer 10 comprising openings only gives way to the rays of the incident useful radiation having an incidence relative to the upper surface of layer 10 comprising openings smaller than a maximum incidence angle a, which is defined by the following relation (1):

tan α=w/h (1)

Ratio h/w may vary from 1 to 10, or even above 10. Pitch p may vary from 1 μm to 100 μm, for example equal to approximately 15 μm. Height h may vary from 0.1 μm to 1 mm, particularly from 1 μm to 800 μm, preferably from 10 μm to 130 μm or from 1 μm to 100 μm. Width w may vary from 0.1 μm to 100 μm, for example, equal to approximately 2 μm. Holes 26 may all have the same width w. As a variant, holes 26 may have different widths w.

FIG. 3 is a cross-section view of a variant of the optical system 5 shown in FIG. 1 where coating 16 comprises only layer 18, which corresponds to a film applied against microlens array 14. In this case, the contact area between lens 18 and microlenses 14 may be decreased, for example, limited to the tops of microlenses 14.

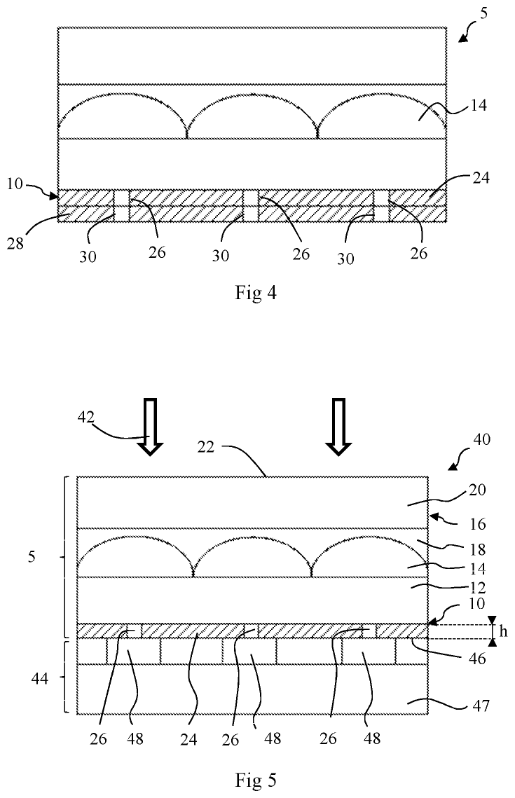

FIG. 4 is a cross-section view of another variant of optical system 5 shown in FIG. 1 where layer 10 comprising openings comprises an additional opaque layer 28 covering opaque layer 24, on the side of opaque layer 24 opposite to microlenses 14, and crossed by holes 30 located in line with holes 26. An intermediate layer, transparent to the useful radiation, may be interposed between opaque layers 24 and 28. Generally, layer 10 comprising openings may comprise a stack of more than two opaque layers, each opaque layer being crossed by holes, the opaque layers of each pair of adjacent opaque layers being spaced apart or not by one or a plurality of transparent layers.

According to an embodiment, layer 24 is totally made of a material absorbing and/or reflective at least for the wavelengths to be angularly filtered of the useful radiation.

According to an embodiment, layer 24 is made of a positive resist, that is, a resist for which the portion of the resin layer exposed to a radiation becomes soluble to a developer and where the portion of the resist layer which is not exposed to the radiation remains non-soluble in the developer. Opaque layer 24 may be made of colored resin, for example, a colored or black DNQ-Novolack resin or a DUV (Deep Ultraviolet) resist. DNQ-Novolack resins are based on a mixture of diazonaphtoquinone (DNQ) and of a novolack resin (phenolformaldehyde resin). DUV resists may comprise polymers based on polyhydroxystyrenes.

According to another embodiment, layer 24 is made of a negative resist, that is, a resist for which the portion of the resin layer exposed to a radiation becomes non-soluble to a developer and where the portion of the resist layer which is not exposed to the radiation remains soluble in the developer. Examples of negative resists are epoxy polymer resins, for example, the resin commercialized under name SU-8, acrylate resins, and off-stoichiometry thiolene (OSTE) polymers.

According to another embodiment, layer 24 is made of a laser-machinable material, that is, a material capable of degrading under the action of a laser radiation. Examples of laser-machinable materials are graphite, plastic materials such as poly(methyl methacrylate) (PMMA), acrylonitrile butadiene styrene (ABS), or dyed plastic films such as polyethylene terephthalate (PET), poly(ethylene naphthalate) (PEN), cyclo olefin polymers (COP), and polyimides (PI).

Further, as an example, layer 24 may be made of black resin absorbing in the visible range and/or in near infrared. According to another example, opaque layer 24 may further be made of colored resin absorbing visible light of a given color, for example, blue, green, or cyan light. This may be the case when optical system 5 is used with an image sensor which is only sensitive to light of a given color. This may further be the case when optical system 5 is used with an image sensor which is sensitive to visible light and a filter of the given color is interposed between the image sensor and the object to be detected, for example, between layer 10 comprising openings and intermediate layer 12.

When layer 10 comprising openings is formed of a stack of at least two opaque layers 24, 28, each opaque layer may be made of one of the previously-mentioned materials, and the opaque layers may be made of different materials.

Holes 26, 30 may be filled with air or filled with a material at least partially transparent to the useful radiation, for example polydimethylsiloxane (PDMS). As a variant, holes 26, 30 may be filled by a partially absorbing material to filter the wavelengths of the rays of the useful radiation. Optical system 5 may then further play the role of a wavelength filter. This enables to decrease the thickness of system 5 with respect to the case where a colored filter distinct from optical system 5 would be present. The partially absorbing filling material may be a colored resin or a colored plastic material such as PDMS.

The filling material of holes 26, 30 may be selected to have a refraction index matching with intermediate layer in contact with layer 10 comprising openings or to rigidify the structure and improve the mechanical resistance of layer 10 comprising openings. Further, the filling material may also be a liquid or solid adhesive material enabling to assemble optical system 5 on another device, for example, an image sensor. The filling material may also be an epoxy or acrylate glue used for the encapsulation of the device having the optical system resting on a surface thereof, for example, an image sensor, considering that layer 12 is an encapsulation film. In this case, the glue fills holes 26 and is in contact with the surface of the image sensor. The glue also enables to laminate the optical system on the image sensor.

Intermediate layer 12, which may be omitted, is at least partially transparent to the useful radiation. Intermediate layer 12 may be made of a transparent polymer, particularly of PET, of PMMA, of COP, of PEN, of polyimide, of a layer of dielectric or inorganic polymers (SiN, SiO₂), or of a thin glass layer. As previously indicated, layer 12 and microlens array 14 may correspond to a monolithic structure. Further, layer 12 may correspond to a layer of protection of the device, for example, an image sensor, having optical system 5 attached thereto. If the image sensor is made of organic materials, layer 12 may correspond to a water- and oxygen-tight barrier film protecting the organic materials. As an example, this protection layer may correspond to a SiN deposit in the order of 1 μm on the surface of a PET, PEN, COP, and/or PI film in contact with layer 10 comprising openings.

According to an embodiment, there are as many microlenses 14 as holes 26. Preferably, the layout of microlenses 14 follows the layout of holes 26. In particular, the pitch between the optical centers of adjacent microlenses 14 is the same as the previously-described pitch p of holes 26

According to another embodiment, microlenses 14 may have, in top view, a polygonal base, particularly square, rectangular, pentagonal, or hexagonal. Preferably, microlenses 14 substantially meet, in top view. According to another embodiment, microlenses 14 may have, in top view, a circular or oval base.

Preferably, the focal planes of microlenses 14 are confounded. The focal planes of microlenses 14 may be located substantially across the thickness of opaque layer 24 or at a distance from opaque layer 24. According to an embodiment, microlenses 14 all have the same shape. According to another embodiment, microlenses 14 have different shapes. Microlenses 14 may be made of silica, of PMMA, of positive resist, of PET, of PEN, of COP, of PDMS/silicone, or of epoxy resin. Microlenses 14 may be formed by flowing of resist blocks. Microlenses 14 may further be formed by molding on a layer of PET, PEN, COP, PDMS/silicone or epoxy resin.

Coating 16 is at least partially transparent to the useful radiation. Coating 16 may have a maximum thickness in the range from 0.1 μm to 10 mm. Upper surface 22 may be substantially planar or have a curved shape.

According to an embodiment, layer 18 is a layer which follows the shape of microlenses 14. Layer 18 may be obtained from an optically clear adhesive (OCA), particularly a liquid optically clear adhesive (LOCA), or a material having a low refraction index, or an epoxy/acrylate glue, or a film of a gas or of a gaseous mixture, for example, air. Preferably, when layer 18 follows the shape of microlenses 14, layer 18 is made of a material having a low refraction index, lower than that of the material of microlenses 14. Layer 18 may be made of a filling material which is a non-adhesive transparent material. According to another embodiment, layer 18 corresponds to a film which is applied against microlens array 14, for example, an OCA film. In this case, the contact area between layer 18 and microlenses 14 may be decreased, for example, limited to the tops of the microlenses. Layer 18 may then be made of a material having a higher refraction index than in the case where layer 18 follows the shape of microlenses 14. According to an embodiment, layer 20 may be made of one of the materials previously indicated for layer 18. Layer 20 may be omitted. The thickness of layer 20 is in the range from 1 μm to 100 μm.

An example of application of the optical system will now be described for an angular filter of an image acquisition system.

FIG. 5 is a partial simplified cross-section view of an embodiment of an image acquisition system 40 receiving a radiation 42. Image acquisition system 40 comprises, from bottom to top in FIG. 5:
an image sensor 44 having an upper surface 46; and
optical system 5 forming an angular filter and covering surface 46.

Image sensor 44 comprises a support 47 and an array of photon sensors 48, also called photodetector, arranged between support 47 and optical system 5. Photodetectors 48 may be covered with a transparent protection coating, not shown. Image sensor 44 further comprises conductive tracks and switching elements, particularly transistors, not shown, enabling to select photodetectors 48. In FIG. 5, the photodetectors are shown as spaced apart by a substantially constant pitch. Photodetectors 48 may be made of organic materials. Photodetectors 48 may correspond to organic photodiodes (OPD), to organic photoresistors, to amorphous silicon photodiodes associated with an array of CMOS transistors. The surface area of image sensor 44 opposite optical system 5 and containing photodetectors 48 is greater than 1 cm², preferably greater than 5 cm², more preferably greater than 10 cm², in particular greater than 20 cm². The upper surface 46 of image sensor 44 may be substantially planar.

According to an embodiment, each photodetector 48 is capable of detecting an electromagnetic radiation in a wavelength range from 400 nm to 1,100 nm. All photodetectors 48 may be capable of detecting an electromagnetic radiation in the same wavelength range. As a variation, photodetectors 48 may be capable of detecting an electromagnetic radiation in different wavelength ranges.

Image acquisition system 40 further comprises means, not shown, for processing the signals output by image sensor 44, for example comprising a microprocessor.

Angular filter 5, covering image sensor 44, is capable of filtering incident radiation 42 according to the incidence of radiation 42 relative to upper surface 22, particularly so that each photodetector 48 only receives the rays having an incidence relative to an axis perpendicular to upper surface 22 smaller than a maximum angle of incidence smaller than 45°, preferably smaller than 30°, more preferably smaller than 20°, more preferably still smaller than 10°. Angular filter 5 is capable of blocking the rays of the incident radiation having an incidence relative to an axis perpendicular to upper surface 22 greater than the maximum angle of incidence.

According to an embodiment, photodetectors 48 may be distributed in rows and in columns. In FIG. 5, the pitch of photodetectors 48 is the same as the pitch of holes 26. Layer 10 comprising openings is then preferably aligned with image sensor 44 so that each hole 26 is located opposite a photodetector 48. According to another embodiment, the pitch p of holes 26 is smaller than the pitch of the photodetectors 48 of image sensor 44. In this case, a plurality of holes 26 may be located opposite a photodetector 48. According to another embodiment, the pitch p of holes 26 is greater than the pitch of the photodetectors 48 of image sensor 44. In this case, a plurality of photodetectors 48 may be located opposite a hole 26.

Another example of application of optical system 5 will now be described for a collimation device of a lighting or display system.

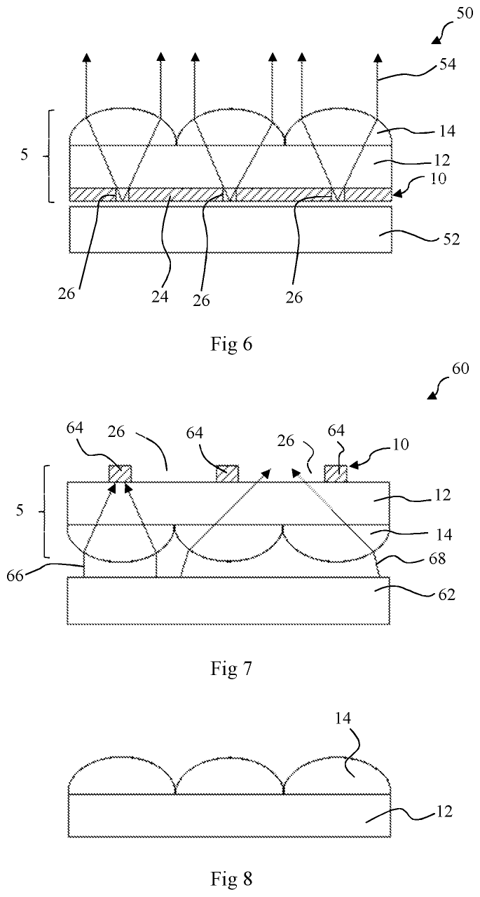

FIG. 6 is a partial simplified cross-section view of an embodiment of an illumination system 50 outputting a collimated light. Illumination system 50 comprises, from bottom to top in FIG. 6:
a light source 52 emitting a non-collimated radiation 54; and
the optical system 5 such as previously described, covering light source 52 and receiving the radiation 54 supplied by light source 52, coating 16 being not present in FIG. 6, layer 10 comprising openings being interposed between light source 52 and microlens array 14.

Preferably, the emission plane of light source 52 is close to the focal plane of optical system 5. Further, according to the envisaged application, the form factor (height-to-width or aspect ratio) of the holes 26 of layer 10 should be sufficiently high for no ray coming out of an opening 26 opposite a given microlens 14 to cross a neighboring microlens. Indeed, in this case, the output ray would not be collimated. As previously mentioned, the aperture angle of layer 10 may be adjusted by the aspect ratio of openings 26.

In the present embodiment, optical system 5 plays the role of a collimation device which enables to collimate the radiation 54 output by light source 52. In FIG. 6, light source 52 is shown with a substantially planar emissive surface. As a variant, the emissive surface of light source 52 may be curved.

Another example of application of optical system 5 will now be described for a lighting system screening device.

FIG. 7 is a partial simplified cross-section view of an embodiment of a lighting system 60. Lighting system 60 comprises, from bottom to top in FIG. 7:
a light source 62 emitting a radiation; and
the optical system 5 such as previously described, covering light source 62 and receiving the radiation emitted by the latter, coating 16 being absent from FIG. 7, microlens array 14 being interposed between light source 62 and layer 10 comprising openings.

In the present embodiment, layer 10 comprising openings comprises opaque pads 64, each pad 64 being located opposite a microlens 14 and being surrounded with a hole 26, holes 26 communicating with one another. In the present embodiment, optical system 5 plays the role of a screen configured to block the rays 66 emitted by light source 62 substantially perpendicularly with respect to the emission surface of light source 62 and gives way to rays 68 inclined with respect to the emission surface of light source 62. Such a lighting system 60 may be in particular used in microscopy where a diffused lighting may be desirable.

Another example of application of optical system 5 comprises the use of optical system 5 as a mask in a photolithography method.

FIGS. 8 to 12 are partial simplified cross-section views of structures obtained at successive steps of an embodiment of a method of manufacturing the optical system 5 shown in FIGS. 1 and 2.

FIG. 8 shows the structure obtained after the forming of microlens array 14 on intermediate layer 12. As a variant, microlens array 14 may be formed on a support different from intermediate layer 12, this support being removed before the forming of intermediate layer 12 when intermediate layer 12 is present, or before the forming of layer 10 comprising openings when intermediate layer 12 is not present. According to an embodiment, the manufacturing of microlenses 14 comprises the forming of a layer of the material forming microlenses 14 on intermediate layer 12 or another support and the deformation of this layer, for example, by means of an array to form the microlenses. According to another embodiment, microlenses 14 are formed by molding.

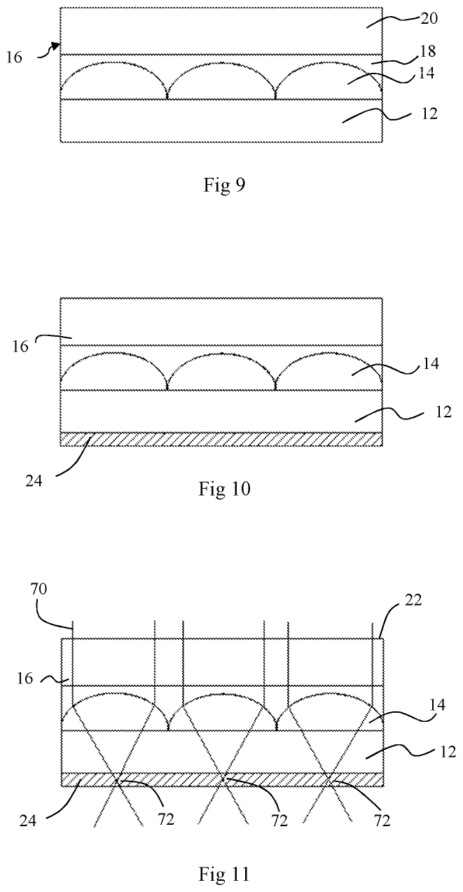

FIG. 9 shows the structure obtained after the forming of coating 16 on microlens array 14 when coating 16 is present. When coating 16 is not present, the steps described hereafter in relation with FIG. 10 may be directly carried out after the steps previously described in relation with FIG. 8. According to an embodiment, the forming of coating 16 may comprise the steps of:
depositing a liquid or viscous layer of the material forming layer 18 on microlens array 14. The liquid layer thus follows the shape of microlenses 14. This layer is preferably self-planarizing, that is, it automatically forms a substantially planar free surface;
curing the liquid layer to form layer 18. This may comprise a step of crosslinking of the material forming layer 18, particularly by thermal crosslinking and/or by irradiation by an ultraviolet beam; and
forming layer 20 on layer 18, or in contact with microlens layer 14 when layer 18 is not present, for example, by lamination of a film on layer 18.

FIG. 10 shows the structure obtained after the forming of opaque layer 24 on intermediate layer 12, on the side opposite to microlens array 14. Opaque layer 24 may be deposited by liquid deposition, by cathode sputtering, or by evaporation. Methods such as spin coating, spray coating, heliography, slot-die coating, blade coating, flexography, or silk-screening, may in particular be used. According to the implemented deposition method, a step of drying of the deposited material may be provided.

FIG. 11 shows the structure obtained during a step of exposure to a radiation 70, crossing the microlenses 14 of portions 72 of opaque layer 24 at the desired locations of holes 26. The radiation used to expose opaque layer 24 depends on the resist used. As an example, radiation 70 is a radiation having wavelengths approximately in the range from 300 nm to 450 nm in the case of a DNQ-Novolack resin or an ultraviolet radiation for a DUV resist. The duration of the exposure of opaque layer 24 to radiation 70 particularly depends on the type of positive resist used and is sufficient for the exposed portions 72 of opaque layer 24 to extend across the entire thickness of opaque layer 24.

The exposure of opaque layer 24 is performed through microlenses 14. Opaque layer 24 is then preferably located in the focal plane of microlenses 14 or close to the focal plane of microlenses 14. According to an embodiment, the incident radiation 70 which reaches microlenses 14 is a substantially collimated radiation so that it is focused by each microlens 14 substantially at the level of opaque layer 24 or close to opaque layer 24. Opaque layer 24 may be offset with respect to the focal plane of microlenses 14 to obtain spots of desired dimensions on opaque layer 24 when opaque layer 24 is exposed to a radiation 70 through microlenses 14. Preferably, the inclination of radiation 70 relative to upper surface 22 substantially corresponds to the average inclination formed by the radiation 6 captured by photodetectors 48 with upper surface 22 during a normal use of image acquisition system 5. According to an embodiment, radiation 70 is substantially perpendicular to layer 24. According to another embodiment, radiation 70 is inclined with respect to a direction perpendicular to layer 24, thus enabling to obtain holes 26 offset with respect to the microlenses. In FIG. 11, holes 26 are cylindrical, that is, their cross-section area is constant. However, as previously described, the cross-section area of holes 26 may not be constant. As an example, holes 26 may have a tapered shape. According to another embodiment, incident radiation 70 exhibits a divergence, for example, with a divergence angle greater than 1°, the divergence angle of the incident radiation 70 which reaches microlenses 14 then being adjusted to modulate the width of the holes 26 formed in layer 24.

According to another embodiment, particularly when coating 16 is not present, a layer of a material having an adapted refraction index may be temporarily arranged on microlens array 14 during the exposure step to modify the focal distance of microlenses 14 so that the exposed portions 72 have the desired dimensions.

According to an embodiment, the light source emitting exposure radiation 70 may be displaced with respect to microlens array 14 during the exposure step according to the desired shape of holes 26. As an example, the light source emitting exposure radiation 70 may be displaced in a loop, which enables to obtain holes 26 of ring-shaped cross-section. Such a hole shape particularly enables to form a bandpass angular filter authorizing the passage of rays having an incidence relative to a direction orthogonal to surface 22 at least in a first incidence range and of giving way to rays having an incidence relative to a direction orthogonal to surface 22 at least in a second incidence range distinct from said at least one first incidence range.

According to an embodiment, microlenses 14 may have different focusing points according to the wavelength of exposure radiation 70. Resist layer 24 may be sensitive to these different wavelengths. As a variant, when layer 10 comprising openings comprises a stack of a plurality of photosensitive layers, each photosensitive layer may be sensitive to a radiation at a specific wavelength. The exposure step may then comprise the exposure of the photosensitive layer or of the photosensitive layers to radiations at these different wavelengths to obtain holes 26 of desired shape.

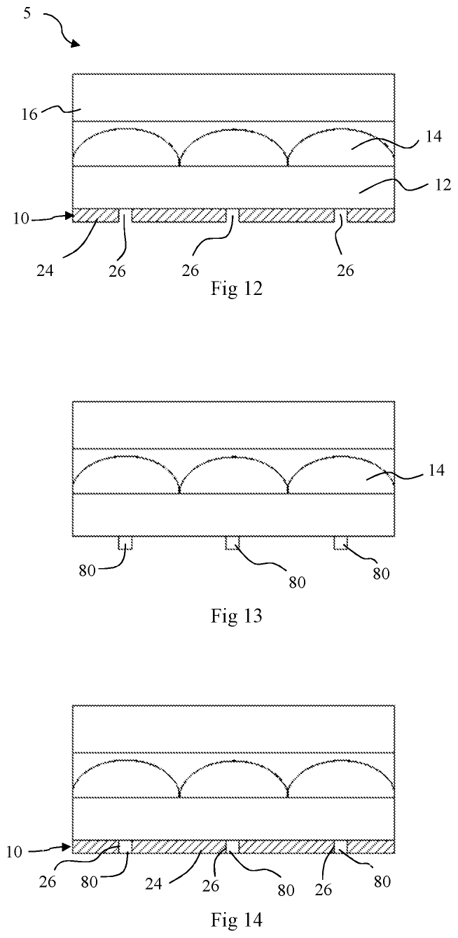

FIG. 12 shows the structure obtained during a step of development of opaque layer 24 which has caused the dissolution, in a developer, of the portions 72 of opaque layer 24 exposed to incident radiation 70, thus forming holes 26. Layer 10 comprising openings is thus obtained. The composition of the developer depends on the nature of the positive resist which has been used.

The method may comprise subsequent steps comprising the filling of holes 26 with a filling material and the bonding of the optical system 5 thus obtained to image sensor 44.

FIGS. 13 and 14 are partial simplified cross-section views of structures obtained at successive steps of another embodiment of a method of manufacturing the optical system 5 shown in FIGS. 1 and 2.

The initial steps of the present implementation mode of the manufacturing method comprise the steps previously described in relation with FIGS. 8 to 11, with the difference that layer 24 is replaced with a layer of the material intended to fill the holes 26 of layer 10 comprising openings and is made of negative resist which is, further, transparent to the useful radiation.

FIG. 13 shows the structure obtained during a step of development of the negative resist which has caused the dissolving, in a developer, of the portions of the negative resist layer which have not been exposed to the radiation used during the exposure step, the portions of the negative resist later exposed at the exposure step thus forming pads 80. The composition of the developer depends on the nature of the negative resist which has been used.

FIG. 14 shows the structure obtained after the forming of opaque layer 24 between pads 80, for example, by spin coating, spray coating, heliography, slot-die coating, blade coating, flexography or silk-screening. Pads 80 thus delimit holes 26 in layer 24. Layer 10 comprising openings is then thus obtained.

Another embodiment of a method of manufacturing the optical system 5 shown in FIGS. 1 and 2 comprises the steps previously described in relation with FIGS. 8 to 11, with the difference that layer 24 is made of a material capable of degrading under the action of radiation 70, particularly when radiation 70 corresponds to a laser radiation. The illumination of this laser radiation is sufficiently low to avoid damaging the array of micrometer-range optical elements 14 and sufficiently high after the collimation by the array of micrometer-range optical elements 14 to degrade layer 24 at the level of portions 72. At the exposure step previously described in relation with FIG. 11, the portions 72 exposed to radiation 70 are thus destroyed by this radiation, then directly forming holes 26. Layer 10 comprising openings is then thus obtained.

According to an embodiment, the method of manufacturing the optical system may correspond to a roll-to-roll method. According to another embodiment, the optical system manufacturing method may correspond to a sheet-to-sheet method.

When layer 10 comprising openings comprises a stack of at least two layers 24, 28, each comprising holes 26, 30, as shown in FIG. 4, the first layer 24 comprising holes 26 is formed first and the second layer 28 comprising holes 30 is formed afterwards, taking into account the presence of first layer 24, according to any of the previously-described manufacturing method embodiments. A transparent intermediate layer may be present between layers 24 and 28.

Advantageously, the alignment of holes 26 with respect to microlenses 14 is automatically obtained by the very method of forming of holes 26. Further, when layer 10 comprising openings comprises a stack of at least first and second opaque layers, each comprising holes, the alignment of the holes of the second opaque layer with respect to the holes of the first opaque layer is automatically obtained by the very method of forming the holes of the second opaque layer.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional indications provided hereinabove.

1. A method of manufacturing an optical system comprising a layer comprising through or partially through holes and covered with an array of micrometer-range optical elements, the optical system comprising a surface intended to receive a first radiation, the method comprising exposing a film, made of the same material as the layer or of a material different from that of the layer, to a second radiation through the array of micrometer-range optical elements, said material being photosensitive to the second radiation or machinable by the second radiation, and removing the portions of the film exposed or non-exposed to the second radiation to delimit the holes totally or partially crossing said layer.

2. The method according to claim 1, wherein the film is made of resist photosensitive to the second radiation.

3. The method according to claim 2, wherein the layer is made of resist positively photosensitive to the second radiation, the removed portions of the film being the portions exposed to the second radiation.

4. The method according to claim 2, wherein the film is made of resist negatively photosensitive to the second radiation, the removed portions of the film being the portions non-exposed to the second radiation.

5. The method according to claim 1, further comprising machining the layer by a laser beam.

6. The method according to claim 1, wherein the optical system forms an angular filter configured to block the rays of said first radiation having an incidence relative to a direction orthogonal to the surface in at least a first incidence range and to give way to rays of said first radiation having an incidence relative to a direction orthogonal to the surface in at least a second incidence range distinct from said at least one first incidence range.

7. The method according to claim 1, wherein the first radiation is different from the second radiation.

8. The method according to claim 2, wherein the first radiation is in the visible range and/or in the infrared range.

9. The method according to claim 2, wherein the second radiation is in the visible range and/or in the ultraviolet range.

10. The method according to claim 1, further comprising, at the exposure step, placing into contact the array of micrometer-range optical elements with a material, different from air, having a refraction index different from that of the micrometer-range optical elements.

11. The method according to claim 1, wherein the manufacturing of the optical system is performed roll to roll.

12. The method according to claim 1, further comprising, after the forming of the holes, the filling of the holes with a bonding material and the bonding of the layer comprising the holes to a device via the bonding material.

13. The method according to claim 1, wherein the second radiation is collimated.

14. The method according to claim 1, wherein the second radiation has a divergence angle greater than 1°.

15. An optical system comprising a surface intended to receive a first radiation, a layer comprising through or partially through holes and covered with an array of micrometer-range optical elements, the layer being made of a material or the holes being filled with said material, said material being photosensitive to a second radiation or machinable by the second radiation.

16. The optical system according to claim 15, wherein the layer is opaque to the first radiation, the system being configured to block the rays of said first radiation having an incidence relative to a direction orthogonal to the surface in at least a first incidence range and to give way to rays of said first radiation having an incidence relative to a direction orthogonal to the surface in at least a second incidence range distinct from said at least one first incidence range.

17. The optical system according to claim 15, wherein the material is resist photosensitive to the second radiation.

18. The optical system according to claim 15, comprising as many micrometer-range optical elements as holes, the pitch between micrometer-range optical elements being the same as the pitch between holes.

19. The optical system according to claim 15, wherein, for each hole, the ratio of the height of the hole, measured perpendicularly to the surface, to the length of the hole, measured parallel to the surface, varies from 1 to 10.

20. The optical system according to claim 15, wherein the holes are arranged in rows and in columns, the pitch between adjacent holes of a same row or of a same column varying from 1 μm to 100 μm.

21. The optical system according to claim 15, wherein the height of each hole, measured along a direction orthogonal to the surface, varies from 1 μm to 800 μm.

22. The optical system according to claim 21, wherein the height of each hole, measured along a direction orthogonal to the surface, varies from 10 μm to 800 μm.

23. The optical system according to claim 21, wherein the height of each hole, measured along a direction orthogonal to the surface, varies from 1 μm to 100 μm.

24. The optical system according to claim 15, wherein the width of each hole, measured parallel to the surface, varies from 0.1 μm to 100 μm.

25. The optical system according to claim 15, further comprising a stack of said layer comprising said through or partially through holes and of an additional layer comprising additional through or partially through holes aligned with said holes.

26. An image acquisition system comprising an image sensor and an optical system according to claim 15 covering the image sensor and forming an angular filter.

27. The image acquisition system according to claim 26, wherein the image sensor comprises an array of photodetectors, the pitch between photodetectors being equal to, greater or smaller than the pitch between holes.

28. The image acquisition system according to claim 26, wherein the optical system comprises an auxiliary layer playing the role of a protection layer of the image sensor.

29. The image acquisition system according to claim 26, wherein the image sensor is at least partly made of organic materials, and wherein the optical system comprises a water- and/or oxygen-tight film.

30. A lighting or display system comprising a light source and an optical system according to claim 15 covering the light source.
